(19) United States
(12) Patent Application Publication
(10) Pub. No.: US 2014/0178604 A1
(43) Pub. Date: Jun. 26, 2014

(54) Dual-Zone, Atmospheric-Pressure Plasma Reactor for Materials Processing

(71) Applicant: Gary S. Selwyn, Santa Fe, NM (US)

(72) Inventor: Gary S. Selwyn, Santa Fe, NM (US)

(21) Appl. No.: 13/830,300

(22) Filed: Mar. 14, 2013

Related U.S. Application Data
(60) Provisional application No. 61/740,991, filed on Dec. 21, 2012.

(51) Int. Cl. H01J 37/32

(52) U.S. Cl. CPC H01J 37/32357
USPC 427/562; 118/723 ER

(57) ABSTRACT

A substrate is treated with a plasma by passing a gas through a first strong electrical field to form a plasma having active species and ionized species, passing at least a portion of said active species and ionized species into a second, weaker electrical field to generate a second but weaker plasma generation zone. Active species formed in said first plasma or said second plasma impinge onto the substrate to perform the desired treatment. The process allows a greater concentration of active species to reach the substrate than can be formed by the second plasma alone, while reducing arcing, maintaining a low gas temperature and providing other benefits.

### BACKGROUND OF THE INVENTION

The present invention relates to atmospheric pressure plasma reactors and methods for treating a substrate with an atmospheric pressure plasma.

Plasmas are used for a wide variety of material processing applications. Both vacuum-based plasma and atmospheric-pressure plasma have been successfully employed for such applications. Many material processing applications can be carried out more easily at atmospheric pressure because this approach removes the requirement that the workpiece must be vacuum-compatible and does not contain a significant amount of volatile content that may outgas and thereby contaminate the vacuum or the process. In general, the cost of using an atmospheric pressure plasma treatment should be lower than vacuum-based plasma methods because there is no need for the apparatus to generate and maintain a vacuum. This is especially true for roll goods, such as textiles, nonwovens, paper and plastic films, which must be continuously-treated. For these, continuous treatment is easier at atmospheric pressure; similarly, very large substrates are more easily treated using this approach. Medical applications, such as wound treatment, sterilization and decontamination, can be done more easily at atmospheric pressure. The challenge is that atmospheric pressure plasma technology is generally less-developed than vacuum-based plasma technology.

Many plasma applications also require low-temperature processing, where “low temperature” refers to neutral gas temperatures in, or emitted from the plasma, that are at or near ambient. Examples of these would include treatment of temperature-sensitive woven or knitted fabrics, such as wool, silk, rayon, polypropylene and polyamides. Nonwovens, which are often made from temperature sensitive fibers, such as polypropylene, similarly require low temperature processing. There is much interest in room temperature sterilization of skin and complex medical apparatus, such as endoscopes. Thin-film deposition onto temperature sensitive polymers, such as polyethylene or polystyrene can improve the scratch-resistance of these polymers without melting them or changing their visual properties. Another important treatment involving temperature sensitive polymers is for the formation of gas and liquid barrier films on food and beverage packaging. Since these containers are often thermoset plastics, they are, by nature, sensitive to higher temperatures.

Material processing by plasma treatment has been compared to a reactor in which the plasma acts like a chemical generator that produces short-lived, active chemical species from the impact of plasma electrons with components of the feed gas used to fuel the plasma. These active, chemical species typically exist in a short-lived excited state, which cannot otherwise be stored or easily formed. By the impingement of these excited state chemicals onto the substrate, surface reactions provide various desired attributes. Examples of the excited state species include free radicals, such as NH^{•} or NH₂^{•}, atoms such as O, N or H, and even metastable species such as Ar*, Ne*, He*, O₂* and N₂*, where the * refers to an electronically excited state of the noble gas, molecule or atom that has an enhanced lifetime relative to certain other excited states of the same atom. Typically, this results because the excited state metastable is in a different spin state than the ground state species and so cannot release its stored energy by the simple emission of light.

When these active, chemical species impact the substrate, they transfer energy or an unpaired electron to the chemicals present on the surface of the workpiece. This may result in a chemical change, such as monomer polymerization or polymer cross-linking, oxidation, etching, surface rearrangement, or the direct attachment of specific chemical moieties to the surface.

There are two basic requirements for plasma treatment of materials: 1) generation of the desired, active chemical species by the plasma, and 2) transport of these species to impinge the workpiece before they are removed due to gas-phase chemical reactions, quenching or other competing, undesired reactions. By placing the workpiece inside the plasma generation zone (hereafter referred to as an in-situ process) issues relating to the transport of active species can be minimized because of the presence of electrons and ions in the gas-phase environment immediately surrounding the workpiece. However, direct exposure of the workpiece to the plasma generation region can have undesirable effects, such as promoting the out-gassing of contaminants from the workpiece, including water vapor, monomer vapor and other volatile chemicals from the workpiece. Release of these undesired species may interfere with the intended chemical reaction(s) and the contaminant species may also cause the plasma to arc. Plasma arcing can damage or burn the substrate and so is a significant concern for in-situ plasma processing, especially for high power plasma applications.

In “remote” or “down-stream” plasma processing, the plasma generation region is physically separate from the substrate. Active, chemical species are generated in a plasma generation region and are then transported out the plasma generation region to impinge the substrate. Down-stream plasma processing helps to prevent out-gassing from the substrate because the workpiece is physically separated from the location of plasma generation. It also prevents workpiece damage caused by plasma arcing events. The difficulty in downstream plasma processing is the need to transport the active chemical species to the substrate before they extinguish due to recombination and other surface and gas-phase reactions. This can be accomplished by using a high velocity flow of gas through the plasma generation zone and then onto the substrate. Because of this, downstream processing can be expensive, especially when expensive noble gases such as helium are used to generate the plasma and to increase the linear velocity of the gas flow.

In summary, in-situ processing reduces the gas flow required for materials treatment, but introduces problems with plasma-initiated out-gassing and creates a susceptibility to arcing and consequent substrate damage, whereas downstream processing minimizes arcing issues and out-gassing, but requires a high gas flow for efficient treatment, which can be expensive.

Another important consideration for plasma treatment of materials is the concentration of active species/unit volume produced by the plasma. Increasing the power density (W/cm³) of a plasma generally increases the ionization density of a plasma and more electrons/cm³ also generally produces more active chemical species/cm³, which increases processing speed. Higher power atmospheric-pressure plasmas are therefore desirable for material processing applications because such plasmas increase the speed at which the workpiece is treated. (See A. Schutze, J. Y. Jeong, S. E. Babayan, J. Park, G. S. Selwyn and R. F. Hicks, 1998, “The Atmospheric-Pressure Plasma Jet: A Review and Comparison to Other Plasma Sources”, IEEE Trans. Plasma Sci., 26, 1685.) For in-situ plasma treatment processes, high power plasmas increase processing speed, but can also create increased vulnerability to arcing and substrate damage, as well as undesired chemical reactions from the increased substrate out-gassing. Even subtle changes in the thickness of the substrate caused by folds, seams or weave defects can result in arcing for a high power, in-situ process. For downstream processes, higher power plasmas offer only increasing benefits with no significant negative results, but there remains the problem of transporting the active species to the substrate surface.

The need to have a high power atmospheric pressure plasma source that also operates with a low gas temperature (i.e., <75 C) introduces yet another issue, since the ultimate result of adding energy into a gas is an increase in its kinetic energy, and therefore its temperature. Gases are generally poor thermal conductors, so the required temperature control approach involves both a means for heat removal and a means to improve the thermal conduction of the plasma gases. If done correctly, a high power, atmospheric pressure plasma that operates at a low or near ambient temperature offers significant, materials processing opportunity across a number of different industry sectors.

Various means have been reported for generation of an atmospheric pressure plasma. One common approach is the use of a dielectric-barrier discharge (DBD) in which a dielectric film, such as an electrically-insulating cover, is placed atop one or both of the electrodes. This discharge actually consists of a multitude of short-lived, self-terminating arcs between the electrodes, which continuously start, end and randomly re-form. The dielectric layer serves as a way to terminate the arc and to keep it from becoming self-sustaining, which would damage the electrode and perhaps the substrate. It works this way because the surface of the dielectric becomes charged when the arc forms and this charging eventually terminates the arc. The arc then rapidly reforms elsewhere. (See, e.g., Y. Sawada et al, J. Phys. D: Applied Phys., 28, 1661 (1995) and T. Yokoyama et al., J. Phys. D: Appl. Phys. 23, 1125 (1990)).

Continuously operating DBDs typically operate at relatively low average power: often in the range of 0.05-0.3 W/cm³, roughly equivalent in average plasma density to 1×10⁸ to 1×10⁹ ions/cm³. To aid in this, the use of short pulsed DBD plasma has also been taught, as in the example of U.S. Pat. No. 7,615,931. In the device described in U.S. Pat. No. 7,615,931, a short pulse of dc voltage is applied to an electrode covered with a dielectric. The result is that a very high instantaneous plasma density is achieved; however it is with a relatively low duty cycle and has low average plasma density.

Some DBDs such as those described in U.S. Pat. No., 5,414,324, also use a high ionization energy gas, such as helium, to create a more stable atmospheric plasma. This plasma source also uses a dielectric cover on both electrodes, which are powered at an RMS potential of 1-5 KV at 1-100 KHz. The use of a dielectric cover on the electrode still acts as a barrier for heat removal because dielectric materials are generally poor heat conductors. Because of this, all atmospheric pressure plasmas having a dielectric cover on the electrodes will have difficulty removing heat from the plasma, even if the electrodes are water-cooled. In these, the use of helium as a plasma gas will improve the thermal conductivity of the plasma, but the limiting factor for heat removal remains the poor thermal conductivity of the dielectric cover. These plasmas are also limited in average plasma density due to the presence of the dielectric cover and the impedance to current flow caused by the dielectric cover.

Another form of atmospheric pressure plasma source was described by Selwyn in U.S. Pat. No. 5,961,772. The '772 patent describes the use of “downstream” processing using the pressurized flow rate of the gases inside the plasma to blow reaction products out of the plasma, where they impinge a substrate located several mm downstream of the plasma. A stable, non-arcing atmospheric pressure plasma is generated between a cylindrical, metal electrode that is mounted on one end and which is driven at 13.56 MHz; and a second coaxial, grounded metal electrode that is concentric with the rf electrode. No dielectric cover is used on either electrode. Instead, arcing is prevented by the use of a high (typically >99%) percentage of helium in the gas that flows longitudinally through the uniform and equal, annular gap between the two electrodes. Helium has a low breakdown voltage and is hard to ionize, so it can provide a stable, non-arcing plasma under these conditions.

The '772 patent is differentiated, particularly compared to DBDs, because no dielectric cover is used on either electrode. Higher plasma densities than DBD plasmas can be achieved because there is no dielectric present to impede current flow between the electrode and the plasma. The '772 design is able to generate a power density of about 80 W/cm³, equivalent to a ionization density of about 1×10¹²/cm³ and has a gas temperature that is less 250° C. without water cooling. This ionization density is about 250-1000× greater than most DBD plasmas. Heat removal is accomplished by heat absorption by the feed gas due to the heat capacity of the helium process gas and the high gas flow that is used: it is the helium gas flow that removes heat from the plasma.

The use of water-cooled electrodes that operate on a similar downstream principle to the '772 patent is taught in U.S. Pat. No. 6,262,523. Instead of the coaxial electrode design of the '772 patent, the '523 patent teaches the use of a center, planar electrode that is rf-driven at 13.56 MHz and which is sandwiched between two, equally-spaced, water-cooled, planar ground electrodes. The same gas mixture used in the '772 patent is also used in the '523 patent. In the '523 patent, a majority helium mixture flows through the two planar gaps between the rf and the ground electrodes. The gap spacing between the rf and ground electrodes is between 0.5 and 2.5 mm. At the ends of the electrodes, near the gas outlet of the plasma region, the edges of the ground electrodes and the rf electrodes are rounded to reduce the electrical field at these edges. These edges are the points most vulnerable to arcing.

To enhance the gas flow uniformity and the uniformity of the downstream plasma treatment, the '523 patent does not teach the use of an end-cap of ceramic on the electrodes (such as that used in the '772 patent) to reduce this propensity for arcing at the edges of the electrodes. Because of this, the typical maximum stable power (without arcing) for the '523 design is significantly lower than for the '772 design. An advantage of the '523 design is that is easier to water-cool these electrodes and the design may be scaled up to large size. Units up to 12″ in width have been produced and sold. Another advantage of that design is that multiple sources may be joined together to create a wider plasma source.

U.S. Pat. No. 7,329,608 describes the use of two planar, metal electrode screens, one being rf-driven and the other being grounded. The two planar, screen electrodes are separated by a gap similar to those described in the '772 patent and the '523 patent. The same gas mixture is used in '608 as in the '772 and '523 patents to avoid arcing. In the '608 patent, the gas mixture flows perpendicularly through the two equally-spaced electrode screens, producing a plasma in the gap between the electrodes when the electrode screens are energized. Active species produced in the plasma formed between the electrodes then flows out of the plasma source to impinge the substrate, thereby enabling the downstream treatment of a substrate. The electrode configuration results in a 2-dimensional substrate treatment. However, since a screen electrode cannot be water-cooled to aid in heat removal, the gas flow can be hot.

Gas phase chemistry also becomes especially important when the active species exit the plasma generation region in downstream processes. A good example is the case of atomic oxygen generation, such as may be used for surface cleaning, oxidation or ashing. Inside the plasma generation region, atomic oxygen is generated by electron-impact of O₂, which makes up about 1% of the helium flow in these examples: O₂+e=>2O+e. Since only about 10-20% of the molecular oxygen is dissociated by the plasma, there remains a large percentage of undissociated, molecular oxygen. As taught by Jeong et al. (see Plasma Sources Sci & Technol., 7, 282-285 (1998) and J. Vac. Sci. Technol. A, 17(5), 2581-2585 (1999)), once atomic oxygen is outside of the plasma generation zone, it will rapidly recombine with molecular oxygen to form ozone: O+O₂+M=>O₃+M, where M is any third body in the gas flow, including helium. At atmospheric pressure, the high concentration of M makes this reaction fast, resulting in a short lifetime, or short transit distance, of the atomic oxygen. Because of the short lifetime of atomic oxygen outside of plasma-generating conditions, the helium flow through the plasma and out through the open end must be very fast in order to impinge this active species onto the substrate. This means that either a high helium flow rate is needed or the transit distance to the substrate must be very short. Notably, inside a plasma generation region, this recombination loss reaction is readily reversed, essentially turning it off, due to the energetic impact of electrons with ozone to regenerate the atomic oxygen.

Another downstream, atmospheric-pressure plasma apparatus is taught in U.S. Pat. No. 8,361,276 to Selwyn. In this design, a water-cooled, planar, rf-driven electrode is used together with a parallel row of equally-spaced, tubular ground electrodes, which are cooled by flowing water through the interior of the tubes. Plasma is formed in the gas volume between the planar, water-cooled rf electrode and the array of tubular, water-cooled, ground electrodes. The electrode gap in this invention is in the same range as the '772, '608 and '523 patents. The same gas mixture, consisting of a majority use of helium, is also used. Gas flow enters the plasma through three longitudinal, recessed gas distribution tubes and that gas flow fills the volume between the planar, rf electrode and the array of ground electrode tubes. The active species produced by the plasma then flow out of the plasma volume through the narrow spacing between the linear array of ground electrode tubes and impinge the substrate, providing downstream processing.

The advantage of this design is that the ends of both the rf planar electrode, and the ground electrode tubes, are encased in an insulator, so there is no sharp edge or high radius of curvature that can create a high electric field and thereby lead to arcing. Because the radius of curvature for the ground electrode tubes is the same everywhere in the plasma region, there is no electrode edge that is prone to arcing. Also, because the gas flow is compressed by the spacing between the ground electrode tubes, the gas linear flow velocity is accelerated before striking the substrate without increasing the gas flow. To achieve uniform treatment of the workpiece, it is necessary to uniformly move the workpiece perpendicular to the longitudinal direction of the tubes.

This approach is scalable to large areas. A major advantage is that this design has a large surface area for the ground electrode that helps to remove heat from the plasma. The limiting factor for high power plasma generation becomes the design capability for holding the ground electrode tubes perfectly straight: variations in the gap between ground electrode tubes and the planar, rf electrode will cause the plasma density to be highest wherever the gap dimension is shortest because the electric field will be greatest at these points. If a tube is slightly bent, such that one point is slightly closer to the rf electrode, that spot will become the point of arcing as plasma power is increased. The difficulty in using this invention is that the ground electrode tubes must be held perfectly straight, which is hard to do for a long section, such as 72″ width. Thus, in practice, large units of this design are prone to arcing issues if not properly manufactured.

In addition, the need to efficiently water-cool the full length of the tubes (which is promoted by large diameter tubing) and the need to minimize the transit time of the active species from the plasma to the workpiece (which is promoted by small diameter tubing), are in conflict. If the water flow is not equal through each of the tubes, or if the water flow is not sufficient to handle the power of the plasma, heating of the tubes by thermal exchange with the plasma will result in expansion and deformation, which may lead to arcing as the electrode gap is changed. Finally, contaminants, such as water vapor or monomer vapor that flow into, or are reflected into, the plasma volume, can cause arcing. This can happen if the gas flow that is compressed between the ground electrode tubes is not uniform or is not sufficient to prevent back-flow of gases due to gas reflection from the workpiece. Even trace contaminants inside the plasma can cause arcing if they change the plasma chemistry. Nevertheless, the design of U.S. Pat. No. 8,361,276 represents a substantial improvement from the prior art and it makes downstream processing possible without the extremely high helium consumption and exorbitant cost that would be required to operate the '523 or '608 patents over a large area. The increasing cost of helium and the anticipated short supply of helium gas dictate the prudence of using helium feed gas in an efficient as well as cost-effective manner.

U.S. Pat. No. 5,938,854 describes the use of a DBD plasma that operates using air as a feed gas for in-situ cleaning of substrates. The substrate is located on one of the electrodes and therefore is within the plasma generation zone. Unlike the '772, '523, or '608 non-DBD designs, the inter-electrode gap for DBD plasmas can be large, on the order of several inches. Surface cleaning results from the immersion of the substrate with the plasma and thus also the immersion of the workpiece with the plasma-generated species. This in-situ plasma does not need to “push” the active species out of the plasma with the gas flow. Similarly, Selwyn et al. teach the use of a non-DBD atmospheric pressure plasma that operates with planar, water-cooled, bare metal electrodes and a majority gas mixture consisting of helium plus another reactive gas, such as oxygen, for in-situ removal of photoresist and other cleaning applications in US Patent Application US2006/0048893. However, because the electrode gap is small, 0.5-2.5 mm in this case, the substrate must also be thin, such as a silicon wafer. In-situ treatment of thick substrates, meaning more than 3-4 mm, remains problematic using the approach of US2006/0048893 and other in-situ, non-DBD plasmas.

U.S. Pat. No. 6,228,330 describes the use of two electrodes placed in a concentric design, such as the '772 patent, but at much greater diameter, for decontamination applications. In this, the same electrode gap and the same helium/oxygen gas mixture that that was used in the '772 patent are both employed. Similarly, Selwyn et al. teaches the use of planar electrodes or concentric cylindrical electrodes for cleaning or treatment of flat, roll goods, such as fabric in U.S. Pat. No. 7,023,856. In one embodiment, the cylindrical drum being cleaned is used as an electrode and is treated by in-situ processing. As an additional embodiment, two electrodes may be powered by two different power supplies operating within the same plasma volume with a phase shift between the two power supplies. Gas flow in the '330 patent is perpendicular to the electrodes and is achieved by using an outer (ground) electrode that is perforated to allow gas to pass through the ground electrode.

As is apparent from the foregoing, in-situ processing offers the potential benefit of rapid substrate treatment due to the high density of active, chemical species that can be achieved, but suffers from problems of arcing, especially for high power plasmas. In addition, it is difficult to apply in-situ processing methods to thicker substrates. Downstream plasma processing offers a solution to the arcing problem and can treat thicker substrates, but is expensive due to the need for high gas flow rates to transport the active species and/or long exposure times. Therefore there is a desire to provide an improved plasma treatment process and apparatus that combines the advantages of the downstream plasma with the advantages of an in-situ plasma. This may be done through the use of a dual-zone, atmospheric pressure plasma reactor.

### SUMMARY OF THE INVENTION

This invention is a plasma treatment process which provides the advantages of rapid treatment without a high risk of arcing or the need to provide very high gas flow rates through the apparatus.

In one aspect, this invention is an apparatus for generating an atmospheric pressure or near-atmospheric pressure plasma and directing the plasma-generated active chemical species onto a substrate or workpiece. The apparatus comprises:

a) a radio frequency electrode;

b) a ground electrode spaced apart from the radio frequency electrode to form a first plasma generation zone between the radio frequency electrode and the ground electrode; the first plasma generation zone not being directly in contact with the substrate;

c) an entrance for introducing gas into the first plasma generation zone;

d) a radio frequency power supply electrically connected between the radio frequency electrode and the ground electrode for the purpose of generating a plasma in the first plasma generation zone;

e) a second plasma generation zone that is proximate to, and in fluid communication with, the first plasma generation zone and which is in contact with the substrate and;

f) means for transporting a gas through said first plasma generation zone, then through said second plasma generation zone and onto the substrate.

In some embodiments, the second plasma generation zone includes

g) a secondary electrode spaced apart from the radio frequency electrode at a distance greater than the distance between the radio frequency electrode and the ground electrode in the first plasma region; and

h) grounded support means for holding a substrate within or proximate to the second plasma generation zone.

The invention is also a process comprising for treating a substrate with a plasma, comprising passing a gas at atmospheric or near-atmospheric pressure sequentially through two or more plasma-generating zones, the first of which is not in direct contact with the substrate, the second of which is in contact with the first plasma generation zone and the substrate.

The invention is also a process for treating a substrate with a plasma, comprising

a) disposing a substrate in the grounded support means of an apparatus of the invention;

b) producing a plasma in the first plasma generation zone of an apparatus of the invention;

c) passing metastable and active species produced in the first plasma generation zone into a second plasma generation zone of an apparatus of the invention and onto the substrate.

The invention is also process for treating a substrate with a plasma, comprising passing a gas through a first plasma generation zone having an average power density of 10-500 W/cm³ to form a plasma containing, active species and ionized species, passing at least a portion of said active species and ionized species into a second plasma generation zone having an average power density of 0.05-10 W/cm³ and then impinging species formed in said first plasma generation zone or said second plasma generation zone or both onto the substrate.

By “actives” or “active species” it is meant uncharged species including free radicals (such as NH^{•} or NH₂^{•}), atoms such as O, N or H, and even metastable species such as Ar*, Ne*, He*, O₂* and N₂*, where the * refers to an electronically excited state of the noble gas, molecule or atom.

The present invention offers many important advantages over the prior art. Because the substrate is downstream of the first plasma generation zone, the problems with arc damage to the substrate are avoided, and it is possible to treat somewhat thicker substrates. The concentration of active species in the gas impinging upon the substrate in the second plasma generation zone is greater than is seen in previous downstream plasma treatment processes, so faster treatment rates can be obtained, and it is not necessary to employ the very high gas flow rates that lend significant cost to previous downstream plasma treatment processes. The combination of the two different plasma zones provides materials processing capability that well exceeds the application and benefit of either plasma zone or processing method when used alone.

For either plasma generation region, the process can use, but does not require the use of a dielectric cover on the bare metal electrodes and so can be efficiently water cooled and thereby have a low operating gas temperature (such as 10 to 75° C.).

The apparatus and process of the present invention can be easily scaled up to large size or used as a modular electrode that may be ganged together for combined operation. By the use of a single, large diameter tube for the rf electrode, the present invention avoids the difficulty of keeping multiple, tubular electrodes perfectly aligned, making the present invention less expensive to build and operate. In some embodiments, the present invention avoids arcing problems in the first plasma zone by creating a uniform, concentric electrode gap with no change in the radius of curvature for the primary (first) plasma generation area and it intentionally creates regions of higher and lower plasma power or no plasma generation as a unique design feature that is required for dual plasma zone operation.

Another distinguishing element of certain embodiments of the present invention is the optional addition of a perforated, and passive secondary electrode to create a low-density, second plasma generation region (and in some embodiments, a DBD plasma zone) to help plasma-generated active species transit a longer distance from the first plasma generation zone to the substrate with reduced loss or recombination. In preferred embodiments, this secondary electrode is not directly powered by any external power supply (although a separate power supply can be used, if desired). The preferred embodiments avoid the complication and expense of providing and operating separate power supplies for the rf and secondary electrodes.

### BRIEF DESCRIPTION OF THE DRAWINGS

The accompanying drawings, which are incorporated in and form a part of the specification, illustrate the embodiments of the present invention and, together with the description, serve to explain the principles of the invention.

FIG. 1 is an assembly side view drawing of one embodiment of the invention.

FIG. 2 is a detailed, magnified side view drawing of the bottom half of the embodiment of the invention as shown in FIG. 1.

FIG. 3 is a view of the top and bottom of the embodiment of the invention as shown in FIG. 1 and FIG. 2.

FIG. 4 is a detailed, magnified side view drawing of one embodiment of the invention.

FIG. 5 is a side view of an alternate embodiment of the invention showing the use of planar electrodes for the first plasma region.

### DETAILED DESCRIPTION OF THE INVENTION

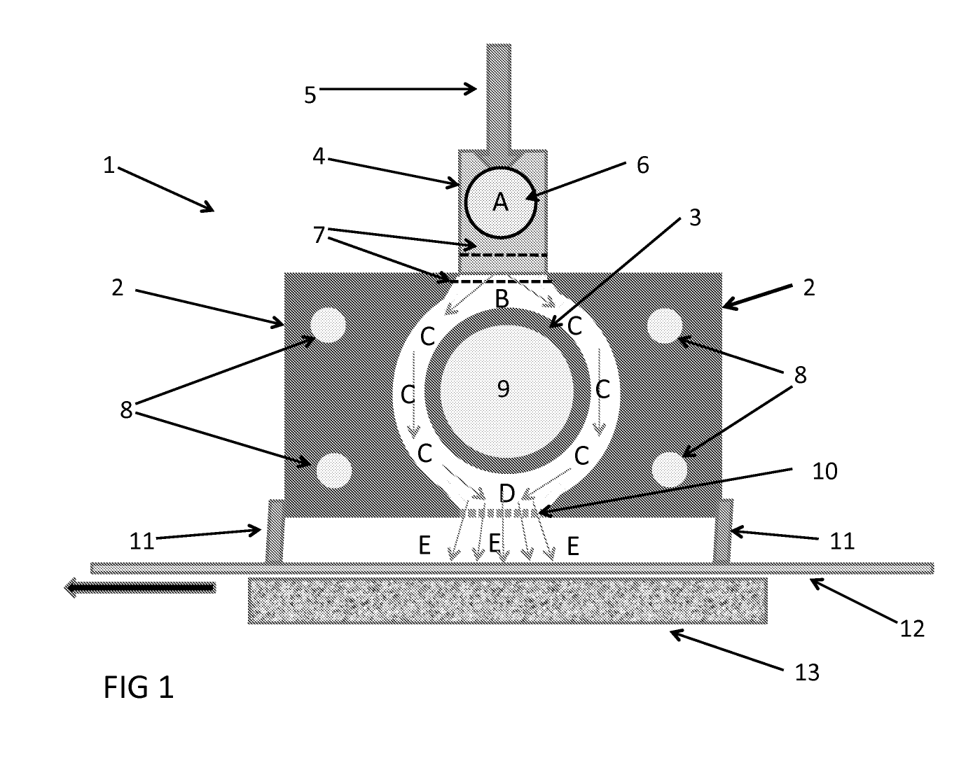

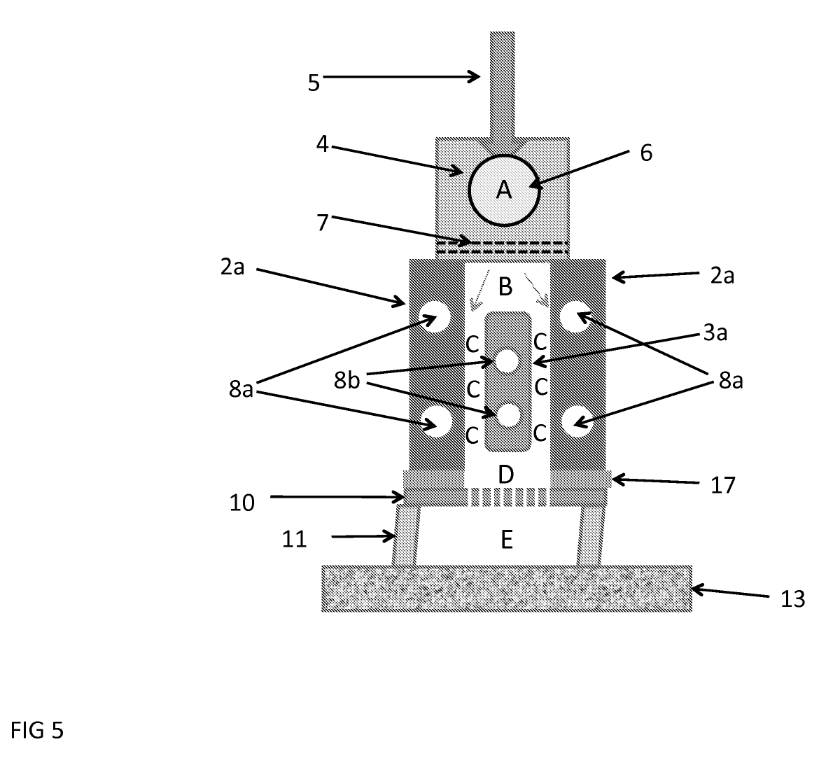

Turning now to FIG. 1, the preferred embodiment of the present invention, apparatus, 1, is shown with gas flow regions denoted by A, B, C, D, and E. Ground electrode 2, which in the embodiment shown consists of 2 parts, each located equidistant from and on either side of radio-frequency electrode 3, which as shown (and as preferred) is water-cooled through center 9. RF electrode 3 is shown as a tubular electrode, but could also be a planar electrode with an internal water cooling channel, in which case ground electrode 2 would be one or planar electrodes spaced equidistant from electrode 3, as shown in FIG. 5. Ground electrode 2 may consist of one or more parts to simplify. As shown, ground electrode 2 includes water cooling channels 8, which may be circular, rectangular, square or some other shape. Ground electrode 2 may be made by attaching two or more sections which have a channel machined into each section to fit a cooling tube or tubes that carry chilled water. Cooling channels 8 may alternately be attached to an outside surface of the electrode and function by conductive cooling through the metal. The importance consideration is that when assembled, ground electrodes 2 should electrically function as a single, electrically-conducting electrode, which has a low resistance to earth ground. It also provides the return current flow to the rf power supply.

Ground electrode 2 and rf electrode 3 may be made from aluminum, stainless steel, brass, copper, nickel, titanium and various alloys of these metals or a conductive non-metallic such as graphite or a conductive polymer. Aluminum is the preferred metal because of its low weight, and excellent thermal and electrical characteristics.

In the embodiment shown, the upper space (proximate to gas baffles 7 in FIG. 1) between the two halves of ground electrode 2 forms an entrance for the introduction of gas into first plasma generating zone (indicated by reference symbols C) defined, as shown, in the gas volume between ground electrode 2 and rf electrode 3, where the interelectrode spacing is constant.

In the embodiment shown, gas distributed from region A via elongated gas distribution housing 4 is first introduced into space B and then into first plasma generating zone C. Region A contains internal gas distribution tube 6. Both housing 4 (which preferably is gas tight at all locations except along its bottom section) and the gas distribution tube 6 preferably extend the full length of ground electrode 2. Gas distribution housing 4 will typically be made from a non-conducting material, such as an acrylic polymer, polycarbonate, Ultem or Plexiglas. Visual clarity through housing 4 is desirable, but not necessary. Gas distribution tube 6 may be micro-porous polymer tubing, such as PTFE, or a solid wall tube with holes drilled it and made from a non-conducting, seamless tube, such as polyethylene.

The means for transporting the gas can be any suitable apparatus such as a blower, bellows, a vacuum pump, one or more pressurized containers which hold the feed gas or various components thereof, various other types of pumps, and the like.

The interior surfaces of ground electrode 2 facing rf electrode 3 preferably are shaped (as shown in FIG. 1) and machined smooth, to be concentric (or equidistant, in the case of a planar electrode) to the exterior surface of rf electrode 3. The interior surfaces of ground electrode 2 preferably have the same radius of curvature where ground electrode 2 borders region C. Similarly, the exterior surfaces of rf electrode 3 preferably have the same radius of curvature in all regions where rf electrode 3 borders region C. Regions C thereby have a constant annular gap. At top (indicated by B), adjacent to the gas inlet, and at bottom (indicated by D), adjacent to secondary electrode 10, the gap between ground electrode 2 to any adjacent surface of electrode 3 is greater than the gap that exists in region C.

As shown, adjacent to flow regions B and D, the shape of ground electrode 2 is tapered, such that the minimum gap between the ground electrode 2 and rf electrode 3 becomes increasingly larger closer to the top and bottom of ground electrode 2. This gap should be 4 mm or greater for the section of ground electrode 2 that contacts the bottom of gas distribution housing 4 in flow region B so that no plasma forms in this region and any plasma formed in region C which may spread to region B will extinguish. In this way, the plasma does not directly contact gas housing 4, or gas baffles 7. This helps to avoid the outgassing of contaminants from the gas housing 4 or gas baffles 7 by reaction with the plasma or active species from the plasma. Also, the gap between secondary electrode 10 and rf electrode 3 in region D is not so large as to extinguish the plasma.

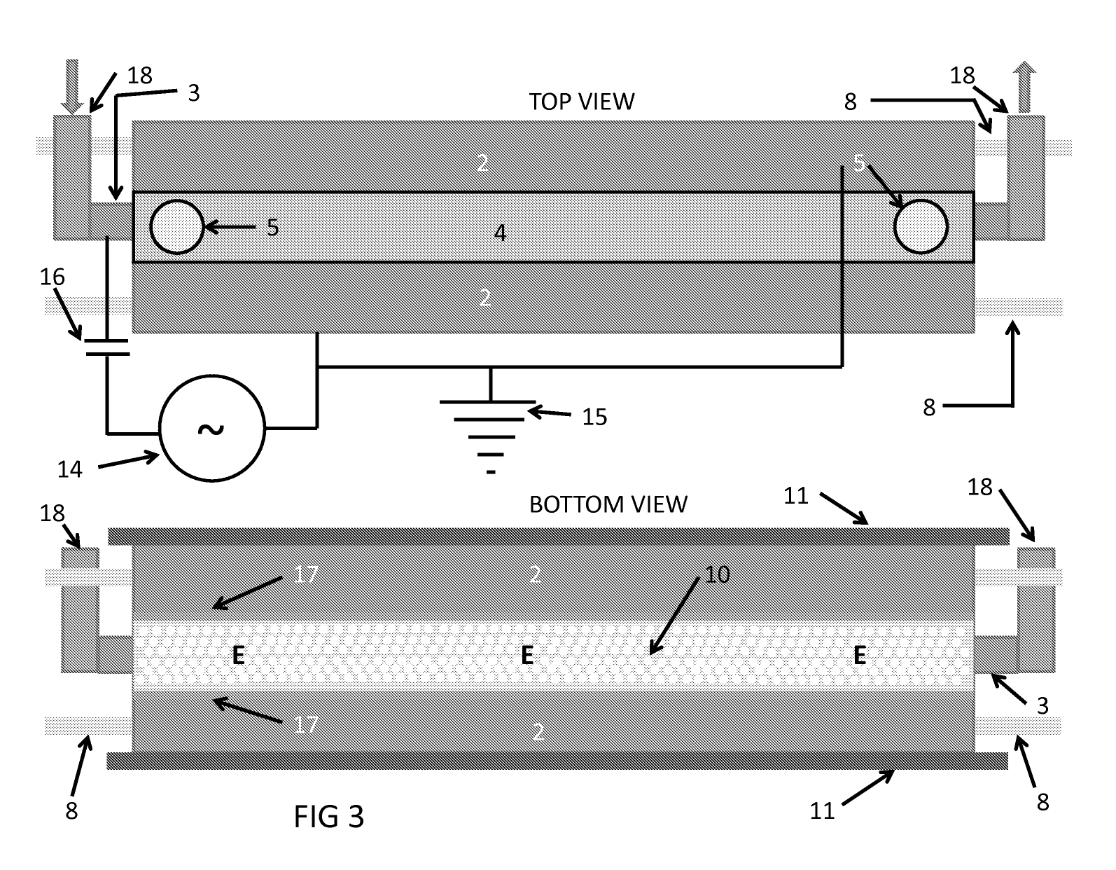

Secondary electrode 10 is fitted at the bottom of ground electrode 2. Secondary electrode 10 includes openings to permit plasma-excited gas phase species to pass through from region D to region E and impact substrate 12. Secondary electrode 10 may have an array of holes or slits, which may be, for example, 0.3-3 mm in diameter for circular holes or 0.3 to 3 mm wide in the case of an array of slits. The holes or slits preferably are evenly-spaced and preferably are staggered to promote uniform exposure of the plasma to the substrate. Sharp edges on these openings should be avoided by rounding the edges of the openings; however, because of the low power plasma that is present in region D and the relatively low electric field present therein, the possibility of arcing is greatly reduced. The width of secondary electrode 10 may be, for example, in the range of 0.25-1× the diameter of rf electrode 3 for a cylindrical design or the same fraction for a planar design. Secondary electrode 10 preferably runs the length of rf electrode 3 electrode as shown in the bottom view of FIG. 3.

Under the conditions described herein, a low power density plasma is formed in the region D, near secondary electrode 10. The low power density plasma formed in region D is controlled, in part, by the gap between secondary electrode 10 and the closest point of rf electrode 3. This gap may be, for example, in the range of 2.5-6 mm, preferably 3.5-5 mm. Because the gap between secondary electrode 10 and the bottom of rf electrode 3 in region D is larger than the interelectrode gap in region C (i.e., the gap between ground electrode 2 and rf electrode 3 in first plasma generation zone C), the plasma here will have a lower power density because the instantaneous electric field is reduced by the larger gap. In one embodiment of the invention, secondary electrode 10 is held close to ground potential by being held in direct electrical contact with ground electrodes 2.

During operation, process gas that enters flow region A is caused to flow into flow region B that is bounded by the gas distribution box 4, ground electrode 2 and rf electrode 3. In the embodiment shown, this is accomplished by providing a gas flow through gas-tight tubing 5 and into gas distribution tube 6 in gas distribution housing 4. Gas tubing 5 is connected to a gas manifold (not shown) as the source of mixed feed gas used to operate the plasma. Gas distribution tube 6 has micro-pores or holes through which the process gas enters and spreads through housing 4. If process gases enter at only one end of gas distribution tube 6, the other end gas distribution tube 6 is sealed closed. The design shown in FIG. 1 permits end-to-end pressure equalization to occur as the gases flow through gas baffles 7 into flow region B. Gas baffles 7 may be optionally provided to create a resistance to gas flow through the baffle(s) such that the gas pressure in region A is slightly greater than the pressure in region B. This helps to create a uniform gas flow across the elongated dimension of the electrode and helps distribute the gas flow uniformly around the two sides of rf electrode 3. Gas baffles 7 are made of a thin, non-conducting material, such as PTFE or a very fine mesh nylon screen, to avoid arcing and plasma formation in region B. It is important to achieve an equal and uniform (along the length of the electrode) gas flow in flow regions C so that the plasma density is equal along both sides of rf electrode 3.

Regions A and B in FIG. 1 are non-plasma regions, i.e., no significant plasma formation or ionization occurs there. The use of non-metallic components for the construction and interconnection of components 4, 5, 6, and 7 ensure this. In preferred embodiments, process gas flowing into region B is cooled by contact with the water-cooled, rf electrode 3. Region B thus serves to pre-chill the process gases by thermal contact with chilled rf electrode 3 even though no plasma is formed in this region. Pre-chilling helps reduce the temperature of the neutral gas that contacts the substrate, even though high power is produced in region C. Pre-chilling of the gas in region B helps to enable low temperature operation of the invention without relying upon a high gas flow to carry heat out of the plasma generation zone. Chilled water or other coolant flows through the interior 9 of rf tubular electrode 3. The chilled water may be cooled to, for example 10-25° C., and preferably to 12-15° C.

An electrical field is generated between ground electrodes 2 and the rf electrode 3 in the first plasma generation zone C due to the application of electrical energy to rf electrode 3 by connection to a radio frequency power supply (not shown in FIG. 1). The plasma formed in flow region C has a high ionization density and is at atmospheric or near atmospheric pressure (such as 0.5 to 2 bar, preferably 0.7 to 1.3 bar). For purposes of this invention, a “high power density is a plasma having a density of 10-500 W/cm³, more typically in the range of 50-350 W/cm³. A high ionization density plasma, for purposes of this invention has an ion density of at least 2×10¹⁰ ions/cm and can be as much as 1×10¹⁴ ions/cm³. The gap between the ground electrodes 2 and the rf electrode 3 in first plasma generation zone C is suitably between 0.5 and 2.5 mm and preferably is about 1.6-2.0 mm. Preferably, this gap is the same in all of first plasma generation zone C and the gas flow rate through all of first plasma generation zone C is the same. Such a small gap promotes high efficiency for heat removal and helps to keep the temperature low for the gases in the plasma, especially when the process gas is rich in helium and the electrodes are water-cooled.

A preferred process gas contains 85-100% helium by weight and preferably contains 95-99.5% helium. The gas flow rate used in the present invention may be, for example between 20 and 200 standard liters per minute (slpm). It is preferably between 35 and 150 slpm for an rf electrode having a 2″ diameter (5 cm) and 72″ (183 cm) long. For smaller or larger electrodes, these gas flow rates can be scaled proportionally. The high thermal conductivity of helium promotes good heat transfer with the electrodes. One or more reactive gases, such as oxygen, nitrogen, ammonia, methane, hydrogen, carbon dioxide, water, hydrogen fluoride, silicon tetrafluoride, tetrafluoromethane or other fluorine-containing gas may be present in the process gas, preferably in the amount of 0.001 to 5% by volume. The plasma-based dissociation of these gases provides the some of the active chemical species that are transported out of main plasma generation region C, and through gas flow regions D and E. Noble gas metastables, atoms, free radicals or metastable molecular nitrogen or oxygen can also function as some or all of the active chemical species.

As active species generated in first plasma generation zone C transit into flow region D and through secondary electrode 10 and thence flow into region E, they impinge substrate 12, which may be stationary or may move perpendicularly across the longitudinal direction of plasma reactor 1. As shown, movement of the substrate 12 is perpendicular to the cross-section view in FIG. 1 as shown by the large arrow (denoting the direction of movement) below substrate 12. On both sides of plasma reactor 1 is optional but preferred flexible gas seal 11, which helps to contain process gases for recycling and also to help avoid loss of active species produced by the plasma before surface reaction on substrate 12. Flexible seal 11 may be comprised of soft silicone rubber or other flexible flap, such as thin PTFE. Flexible seal 11 is designed to gently touch substrate 12 and create a gas flow impedance to help with the containment of process gases and to keep active species produced by the plasma in contact with the substrate for as long as possible. As shown in FIG. 3, bottom view, flexible seal 11 may extend longer than the length of the rf electrode by a small amount, such as 1 to 2 inches (2.54 to 5.08 cm).

Substrate 12 is mounted atop electrically-grounded support 13. Support 13 may be comprised of metal or other electrically-conducting materials. Because it is grounded, support 13 completes the circuit created by the low power, second plasma present in regions D and E. Although it may appear that support 13 and ground electrodes 2 are at the same potential as they both are “grounded” (secondary electrode 10 may also be grounded in some embodiments of the invention), in fact the close proximity of ground electrode 2 to rf electrode 3 and its connection to the return of the rf power supply will result in ground electrode 2 being “bumped” slightly from ground potential. The plasma present in flow region E is due at least in part to the instantaneous electric potential field that exists between secondary electrode 10 and support 13, particularly in preferred embodiments in which secondary electrode 10 is electrically insulated from ground electrode 2 (such as through dielectric medium 17).

Even though charged species are rapidly lost after exiting first plasma generation zone C, some residual amount of these charged species flow into regions D and E. These charged species are believed to increase the electrical conductivity of the gas in regions D and E. The increased electrical conductivity helps to “strike” a plasma and thereby permits additional plasma-generation of active species in the second plasma generation zone, D and E, despite the rather weak electrical field present there.

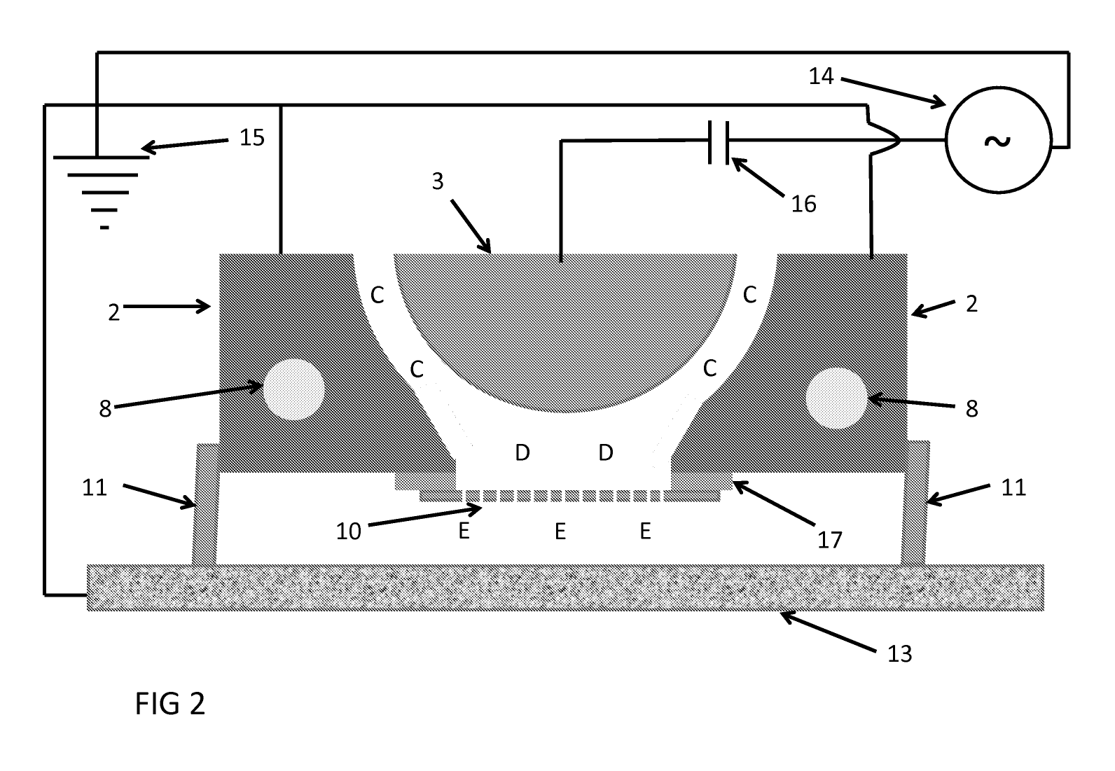

FIG. 2 shows a detailed drawing of the bottom half of FIG. 1 and the electrical connections that are made in the present invention. FIG. 2 also shows a preferred embodiment of the present invention. The powered output of the radio frequency power supply 14 is capacitively-coupled to the rf tubular electrode 3. Power supply 14 operates in the frequency range of 0.4-60 MHz, preferably at 13.56 MHz or other available frequency. Tunable, high voltage capacitor 16 is often embedded in the matching network, not shown in FIG. 2. The matching network acts to tune the coupling of the rf antenna represented by power supply 14 and the electrical connections including the rf electrode 3 such that rf power reflected back into the power supply 14 is minimized and maximum power is coupled into the plasma. Power supply 14 and grounded substrate support 13 are separately connected to earth ground. Ground electrode 2 is connected to the return of power supply 14, such that electrical current flow from rf electrode 3 flows through the first plasma generation zone C, to ground electrode 2 and back to the grounded end of power supply 14.

As shown in FIG. 2, secondary electrode 10 can be physically attached to both sides of ground electrode 2 such that a gas-tight seal is made, except for the gas openings in secondary electrode 10. Gas flow containing active species from the main plasma region C, which originates from both sides of rf electrode 3, combine in flow region D and are directed towards the substrate (not shown in FIG. 2) and support 13 through the openings in secondary electrode 10. In the preferred embodiment, secondary electrode 10 is not in direct electrical contact with ground electrode 2, but instead contacts resistive element 17, which is a dielectric in some embodiments. Resistive element 17 is placed between secondary electrode 10 and ground electrode 2 and thereby electrically isolates secondary electrode 10 from ground electrode 2. Plastic screws (not shown) or other non-conductive attaching means may be used to secure secondary electrode 10 to the underside of ground electrode 2 through resistive element 17.

For the case where secondary electrode 10 has infinite resistance to ground electrode 2 (i.e., secondary electrode 10 is “floating”) and is in contact with the plasma in region D, electrode 10 will come to a floating potential V_{f} which is the potential that is acquired by a floating object placed into the plasma (see B. Chapman, Glow Discharge Processes, John Wiley, pp 51-53 (1980)). This happens because a plasma is an electrically-conductive gas containing equal quantities of both negative and positive charged species. The positively-charged species are always positive ions and the negatively-charged species are combination of electrons and negative ions. Electrons have much greater mobility than ions and so they impact surfaces that are in contact with the plasma at a greater rate than the ions. To avoid greater loss of electrons than positive ions, the surface potential will become slightly negative to balance the rate of loss of charged species and to maintain the requisite equal negative and positive charge density. The potential that is formed by an object placed in contact with the plasma is called the “floating potential”, V_{f}.

In cases in which metal screen 10 is in resistive contact to ground electrode 2, as is the preferred case in the FIG. 1 embodiment due to the presence of resistive element 17 between secondary electrode 10 and ground electrode 2, secondary electrode 10 will have some instantaneous potential Vₐ that is controllable between the floating potential, V_{f}, and the ground potential of ground electrode 2. This potential change comes from the current flow I through resistive element 17, Vₐ=IR, where R is the resistance provided by resistive element 17 and Vₐ is the change in potential for metal screen 10 from the floating potential V_{f}. Through control of the resistance of resistive element 17, it is possible to change the instantaneous potential of secondary electrode 10 and thereby control instantaneous electric field in region D, and in that way, the plasma power density in region D. The instantaneous electric field in region D is determined by Vₐ, which in turn, is determined by the instantaneous voltage of rf electrode 3 and the gap that is present between rf electrode 3 and secondary electrode 10. As that gap will always be greater than the gap that is present in region C, and the instantaneous voltage of secondary electrode 10 will always be reduced from ground electrode 2, the electric field (and thereby the power density) in region D will always be lower than in region C. The resistance of resistive element 17 may be controlled by changing its thickness and/or through selection of its materials of construction. The difference in potential between secondary electrode 10 and grounded support 13 and/or rf electrode 3 creates an electrical field that is weaker than in first plasma generation zone C, but sufficient to generate a plasma in regions D and/or E (i.e., because of the passage of charged species generated in region C that flow into regions D and E). In this way, the plasma in second plasma region D and E is generated using “passive” design elements and it does not require an additional power supply, although one can be supplied for that in one embodiment of this invention. In addition to resistive coupling of secondary electrode 10 to ground electrode 2, secondary electrode 10 can also be capacitively-coupled to ground electrode 2 for the benefit that kind of coupling provides or may be electrically isolated from ground electrode 2. In the former case, a capacitor may be used to electrically-connect secondary electrode 10 to ground electrode 2, or this may be done by using a thin metal film that is sandwiched between two dielectric layers to physically connect secondary electrode 10 to ground electrode 2.

Similarly, the low power density present in region E results from the weak electric field difference between secondary electrode 10 and grounded support 13. Region E is expected to have a lower power density than region D and a much lower power density than region C unless secondary electrode 10 is separately powered using another rf or low frequency (such as a 1-400 KHz) power supply. In that way, the power density in plasma regions C, D and E may each be controlled.

One reason for having a lower power density in region D and especially in region E in comparison to C is to prevent arcing. The presence of a high electric field when exposed to gases that do not contain a high majority of helium causes electrical break-down and thereafter a sustained arc. Contaminant gases, such as those outgassed or evaporated from the substrate by exposure to a plasma, air intrusion, or other impurities can create the conditions for arcing. Arcing can be minimized or even prevented by having a high resistance to current flow from secondary electrode 10 to ground electrode 2 through resistive element 17. When resistive element 17 is highly resistive, it causes electrode 10 to behave similar to a dielectric barrier discharge, where element 17 is the dielectric. In such a case, if arcing does occur, it will be rapidly terminated in the same way a dielectric barrier discharge (DBD) plasma operates, and substrate damage is prevented because the arc is non-sustaining The second plasma generation zone in region E may also be operated in full dielectric barrier discharge mode by placing a dielectric film, such as Al₂O₃ or SiO₂ over grounded, substrate support unit 13 and/or by covering secondary electrode 10 with a dielectric cover.

The apparatus of the invention has only a small capacity to remove heat from the second plasma generation zone. Therefore, another benefit of providing a lower power density in regions D and E is gas heating in these regions by the plasma is minimized.

The gas flow openings in secondary electrode 10 may also be sized to create a “hollow-cathode” effect, based upon the difference between the plasma potential, Vₚ, and the resistance-adjusted floating potential, Vₐ, of a resistively-coupled secondary electrode 10. The instantaneous voltage difference, Vₚ−Vₐ, is responsible for formation of a “sheath” in plasma generation region D that is formed adjacent to secondary electrode 10 and rf electrode 3. That sheath causes reflection of electrons perpendicularly from the sides of the openings in secondary electrode 10, and a local increase in electron energy, called “sheath heating” (see A. E. Wendt and W. N. G. Hitchon, “Electron Heating in Sheaths by Radio Frequency Discharges”, J. Appl. Phys., 71(10), pp 4718-4726, (1992)). By adjusting the openings in secondary electrode 10 such that they are larger in at least one dimension than the sheath thickness, a locally-enhanced plasma is formed through these openings due to the higher energy of the electrons that result from this “focusing” effect. The plasma enhancement that is present inside the openings in secondary electrode 10 produces a plasma “afterglow”, which also protrudes downward, through the openings in secondary electrode 10 and into flow region E. Transit of active species into flow region E, including metastables, free radicals and atomic species, is promoted by this hollow cathode effect, which acts like gas flow accelerator due to the increased drift velocity of charged species through these openings. The formation of this afterglow region in flow region E may be visually observed as slightly increased ribbons of faint light or weak optical emission that protrude from the secondary electrode 10 and into flow region E, ending at the substrate.

The formation of a sheath and the hollow-cathode effect are directly related: ideally, the diameter of the openings in metal screen should be on order of 2× the sheath dimension to get maximum “compression” of the plasma that is created by the reflection of electrons from the sides of the openings in secondary electrode 10. The “plasma compression” and resultant “focusing” of the plasma, caused by the directed acceleration of electrons and ions through the openings in the secondary electrode 10 is believed to result in this hollow-cathode effect, which also helps drive transport of active species produced in region C towards the substrate.

By creating a lower power density over secondary electrode 10 in region D through selection of the resistivity of resistive element 17, a large sheath thickness results, because ionization density and sheath thickness are inversely related. See, for example, N. Goto, J. Appl. Phys., 85, 3074 (1999) or T. Panagopoulos and D. J. Economou, J. Appl. Phys., 85(7), 3435 (1999)). Having a larger sheath thickness in region D (by operating a low power density plasma there) means that the openings in secondary electrode 10 can be larger, in the range of 1-3 mm, and that these larger openings will gain the benefit of the hollow-cathode effect, promoting the formation of a plasma afterglow into flow region E and aiding in the transit of active, chemical species that are formed in region C, but which still need to transit through regions D and E to reach the substrate. This helps to enhance the transit of active species from first plasma generation zone C into the region E, where the active species impinge the workpiece 12. The perforations in secondary electrode 10 also help to increase the linear gas flow velocity in region E, without requiring an increase in gas consumption. This higher linear gas velocity also helps carry active, chemical species from region C to region D to region E, where they impinge the substrate.

A design for providing chilled water to cool the electrodes is illustrated in FIG. 3. A thermostatic, circulating water chiller (not shown) provides a continuous flow of chilled water that passes through the interior 9 of rf tubular electrode 3 through electrically-insulating connectors 18 on both sides of rf tubular electrode 3. Normally, distilled water is used for cooling, as distilled water has the lowest electrical conductivity. Electrically-insulating connectors 18 should have a length of 6-10 feet before connecting between the rf and ground electrodes, to avoid unintended electrical current flow through the fluid. Electrically-insulating connectors 18 can be, for example, plastic, glass or PTFE tubes or combinations thereof.

The top view of FIG. 3 schematically illustrates an electrical connection from output of the rf power generator 14, through capacitive component 16 that may be located inside the matching network (not shown), and the powered output which clamps onto a portion of the metal rf electrode tube 3 that extends beyond the end of the electrode housing. In the embodiment illustrated, ground connections are made to the outside chassis of the rf power supply 14, the two sides of the ground electrode 2, and to the grounded support 13 (not shown in FIG. 3).

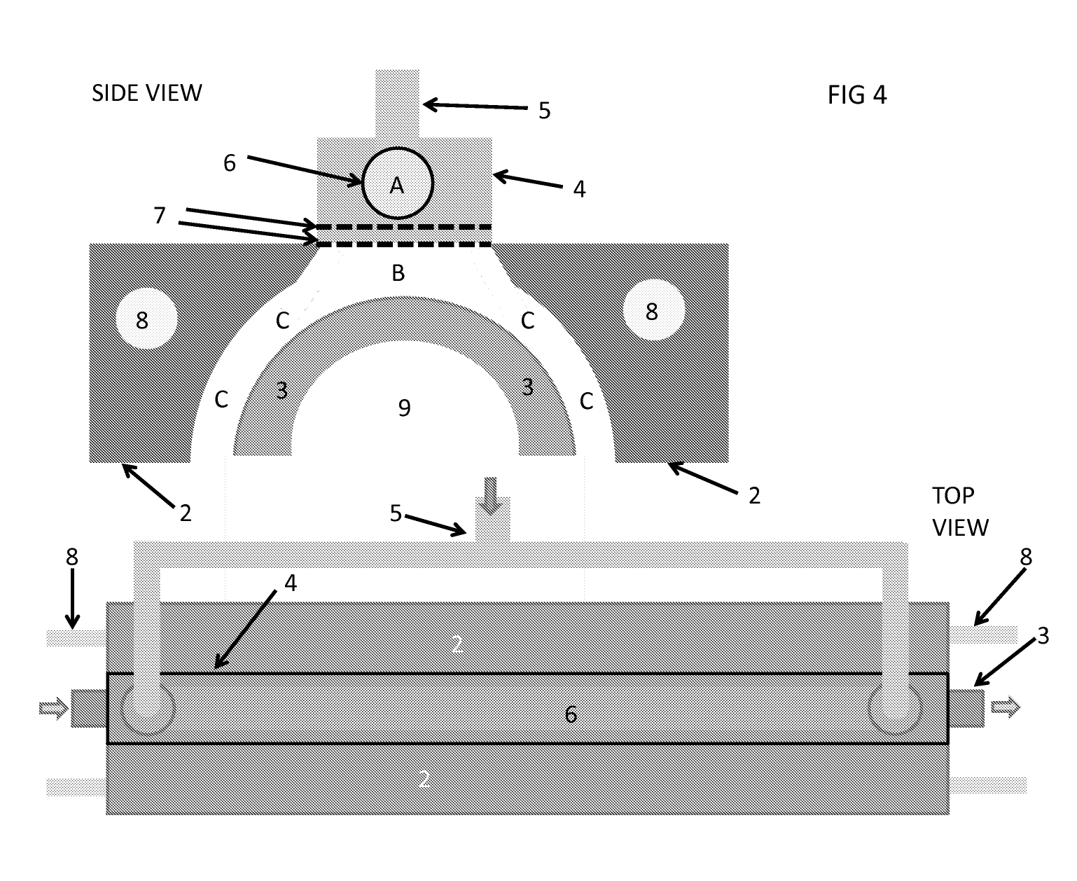

As shown in FIG. 4, gases used to operate the plasma enter through gas tubing 5, which is connected to a gas manifold (not shown) for controlling and mixing of the gases. Gas tubing 5 enters and is sealed around the gas distribution housing 4 to connect to the elongated gas distribution tube 6. All openings and joints in the gas distribution housing (except directly above region B) are sealed to prevent leakage. Typically, tube 5 has connections on both ends of gas distribution tube 6; alternatively, there may also be only one entry point on one end or at the middle of the length of the electrode, in which case one or both ends of gas distribution tube 6 would be sealed off.

During operation, first gas flow is initiated and mixed at or near atmospheric (such as from 50 to 200 kPa, preferably 70 to 130 kPa) pressure. As the process gas exits flow region B and into first plasma generation zone C, it envelops the gap between ground electrodes 2 and tubular or planar rf electrode 3. As gas flow continues through first plasma generation zone C, radio frequency power is applied to rf electrode 3, and a plasma forms in first plasma generation zone C. Electrons formed in the plasma will produce active chemical species, primarily atoms, free radicals and ionic species, by the electron-impact dissociation of the feed gases. Plasma generation zone C is the primary plasma generation zone and that is where most of the generation of the active chemical species needed for material processing applications is produced. The uniform electric field present in flow region C and the large radius of curvature (for the preferred embodiment) in that region helps to prevent arcing. The use of helium as the main component of the process gas allows low gas temperatures to be maintained and there is little likelihood of contaminant gases or air intrusion resulting from the substrate movement for backflow into region C. That cause of arcing is prevented in that way.

Near flow region D, the electrode gap between the ground electrodes 2 and the tubular rf electrode 3 is increased by, for example, chamfering the bottom sides of ground electrodes 2. The resultant increase in the electrode gap reduces the electrical field, which results in a reduction of the power density in region D. The gap from the bottom of rf electrode 3 and secondary electrode 10 is 2.5-6 mm, preferably 3.5-5 mm. Because grounded support 13 is in the vicinity of secondary electrode 10, a weak electrical field exists in region E. The larger gap that is present between secondary electrode 10 and the grounded metal table 13, typically 5-10 mm, and preferably 6-8 mm, results in a smaller, instantaneous electric field that makes arcing less likely to occur in region E.

For faster processing, or to cover more substrate area, multiple, two-zone plasmas may be ganged together, either end-to-end, or in a sequential manner in the direction of movement for the substrate.

A gas flowing through first plasma generation region C is exposed to a high electrical field and forms a high power density plasma. Active species and some of the ionized species formed in region C pass into second plasma generation region D and E, where the feed gas containing these active species and residual charged species is exposed to a second, weaker electrical field. The resultant weak power density plasma that is formed in the second plasma generation region is believed to reduce the recombination of those active species, and in that manner allows more of those active species to impinge upon substrate 12. Without the second plasma generation regions D and E, however, most of the active chemical species produced in region C would be lost by recombination and other reactions before reaching substrate 12.

In addition, it is believed that new active species may also form in second plasma generation regions D and E, through processes such as Penning ionization. In some embodiments, presence of residual charged species in the gas flowing into second plasma generation region D and E from first plasma generation region C increases the electrical conductivity of the gas in second plasma generation region D and E, thereby facilitating the generation of new active species despite the presence of only a weak power density plasma in that region.

Therefore, the gas impinging upon substrate 12 tends to have a higher density of active chemical species than would be expected to be produced in second plasma generation region D and/or E by itself, and more active chemical species than would be expected to survive the transit from first plasma generation zone C to substrate 12 without the second plasma generation region. In addition to the benefit of providing a higher flux of active species, the invention also provides other benefits. For example, a somewhat large diameter rf electrode 3 can be used, which provides better dimensional and operational stability and other benefits. In addition, the substrate can be located outside of the first plasma generation region where a strong electrical field exists, and in that manner the risk of arcing is diminished.

FIG. 5 shows a side view of an alternate embodiment of the present invention that uses planar electrodes for the first plasma generation zone. Components labeled without the use of “a” or “b” attached to the number, are the same as in FIGS. 1-4 and have the same function as given in the specification. Similarly flow regions A, B, C, D and E are the same as in FIGS. 1-4. In FIG. 5, ground electrodes 2a are both planar, and are positioned equidistant from the planar rf electrode 3a, with the same gap as given between ground electrode 2 and rf electrode 3 in FIG. 1. Cooling channels 8a are located inside the ground electrode 2a and planar rf electrode 3a is water cooled using cooling channels 8b. Planar, rf electrode 3a is rounded at the edges to help prevent arcing. The gaps that are present in regions B, C, D, and E are the same as in FIGS. 1-4 and in the description of the preferred embodiment that is detailed in FIG. 1. FIG. 5 does not show the substrate 12, but substrate 12 would be located directly above the grounded substrate support 13.

1. An apparatus for generating an atmospheric pressure or near-atmospheric pressure plasma and directing the plasma-generated active chemical species onto a substrate or workpiece, the apparatus comprising:
a) a radio frequency electrode;
b) a ground electrode spaced apart from the radio frequency electrode to form a first plasma generation zone between the radio frequency electrode and the ground electrode;
c) an entrance for introducing gas into the first plasma generation zone;
d) a radio frequency power supply connected between the radio frequency electrode and the ground electrode for generating a plasma in the first plasma generation zone;
e) a second plasma generation zone that is proximate to, and in fluid communication with, the first plasma generation zone and the substrate and;
f) means for transporting a gas through said first plasma generation zone, then through said second plasma generation zone and onto the substrate.

2. The apparatus of claim 1 wherein the second plasma generation zone includes
g) a secondary electrode spaced apart from the radio frequency electrode at a distance greater than the distance between the radio frequency electrode and the ground electrode in the first plasma region; and
h) grounded support means for holding a substrate within or proximate to the second plasma generation zone.

3. The apparatus of claim 2 wherein the secondary electrode has an instantaneous potential different from ground potential.

4. The apparatus of claim 2 wherein the secondary electrode has openings to allow gas to flow between the first plasma generation zone and the substrate.

5. The apparatus of claim 2 wherein the secondary electrode is not separately powered, and is capacitively-coupled to the ground electrode of the first plasma generation zone.

6. The apparatus of claim 2, wherein the secondary electrode is not separately powered, and is electrically isolated from the ground electrode of the first plasma generation zone.

7. The apparatus of claim 2, wherein the secondary electrode is not separately powered, and is resistively coupled to the ground electrode of the first plasma generation zone.

8. The apparatus of claim 2, wherein the distance from the rf electrode and the ground electrode in the first plasma generation region is 0.5 to 2.5 mm.

9. A process for treating a substrate with a plasma, comprising
a) disposing a substrate in the grounded support means of an apparatus of claim 1;
b) producing an atmospheric pressure or near-atmospheric pressure plasma in the first plasma generation zone of an apparatus of the invention;
c) passing active species produced by the first plasma generation zone into a second plasma generation zone, through openings in the secondary electrode and onto the substrate disposed in the grounded support means.

10. The process of claim 9, wherein the average power density in the first plasma generation zone is 10-500 W/cm³.

11. The process of claim 9, wherein the temperature of the neutral gas in the plasma is between 10 to 75° C.

12. The process of claim 9, wherein the gas contains 85-100% helium.

13. The process of claim 9, wherein the ionization density of the plasma formed in the first plasma generation zone is 2×10¹⁰ ions/cm³ to 1×10¹⁴ ions/cm³.

14. The process of claim 9, wherein the ionization density of the plasma in the second plasma generation zone is 1×10⁷ to 1×10¹⁰ ions/cm³.

15. A process for treating a substrate with a plasma, comprising generating a plasma by passing a gas at atmospheric or near-atmospheric pressure through two or more plasma-generating zones, the first of which is not in direct contact with the substrate, the second of which is in contact with the first plasma generation zone and the substrate; the first plasma generation zone being operated in a “downstream” mode and the second plasma generation zone being operated in an “in-situ” mode.

16. The process of claim 15 wherein the first plasma generation zone has an average power density of 10-500 W/cm³ and the second plasma generation zone has an average power density of 0.05-10 W/cm³ and active species formed in said first plasma generation zone or said second plasma generation zone or both are impinged onto the substrate.

17. An atmospheric-pressure plasma processing apparatus wherein the entrance for introducing gas into the plasma generation zone comprises an electrically-nonconducting, elongated gas distribution housing in fluid communication with a gas manifold and the plasma generation zone and sealed on all ends except the entrance to the plasma generation zone.

18. The apparatus of claim 17 wherein said at least one gas distribution housing further comprises a porous tube disposed within said gas distribution housing in fluid communication with said gas manifold for supply of process gases to the plasma generation zone;

19. The apparatus of claim 17 wherein said porous tube comprises a micro-porous polymer tube.

20. The apparatus of claim 17 wherein said micro-porous polymer tube comprises a PTFE tube.
